(19) United States
(12) Patent Application Publication
(10) Pub. No.: US 2025/0160131 A1
(43) Pub. Date: May 15, 2025

(54) DISPLAY PANEL AND PREPARATION METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Kening ZHENG, Beijing (CN); Changlong YUAN, Beijing (CN); Tong WU, Beijing (CN)

(21) Appl. No.: 18/837,450

(22) PCT Filed: Sep. 26, 2023
(86) PCT No.: PCT/CN2023/121711

§ 371 Date: Aug. 9, 2024

(30) Foreign Application Priority Data
Nov. 30, 2022 (CN) 202211528685.8

(51) Int. Cl. H10K 59/122; H10K 59/12

(52) U.S. Cl. CPC H10K 59/122; H10K 59/1201

(57) ABSTRACT

Disclosed is a display panel, including a substrate, a pixel definition layer, a plurality of pixel structures, a transparent cathode patterning material (CPM) layer, and a plurality of cathode layers, wherein the pixel definition layer is provided with a plurality of pixel openings; the plurality of pixel structures are disposed in different pixel openings; the transparent CPM layer is disposed on a side, away from the substrate, of the pixel definition layer, and the transparent CPM layer is provided with a plurality of cathode openings, wherein in a thickness direction of the substrate, an orthographic projection of a cathode opening covers an orthographic projection of a pixel opening; and each of the cathode layers is disposed on a side, away from the pixel definition layer, of the pixel structure, and a position of each of the cathode layers corresponds to a position of one cathode opening.

### CROSS-REFERENCE TO RELATED APPLICATIONS

This application is a U.S. national phase application based on PCT/CN2023/121711, filed on Sep. 26, 2023, which is based on and claims priority to Chinese Patent Application No. 202211528685.8, filed on Nov. 30, 2022, and entitled “DISPLAY PANEL AND PREPARATION METHOD THEREFOR, AND DISPLAY DEVICE”, all of which are hereby incorporated by reference in their entireties for all purposes.

### TECHNICAL FIELD

The present disclosure relates to the field of display technologies, and in particular, relates to a display panel and a preparation method therefor, and a display device.

### BACKGROUND

With the rapid development of the information age, organic light-emitting diode (OLED) display technology has gradually become an indispensable part of display technology due to its advantages of self-illumination, wide viewing angle, thin and light, low energy consumption, and bendability.

### SUMMARY

Embodiments of the present disclosure provide a display panel and a preparation method therefor, and a display device. The technical solutions are as follows.

In a first aspect, the embodiments of the present disclosure provide a display panel. The display panel includes a substrate, a pixel definition layer, a plurality of pixel structures, a transparent cathode patterning material (CPM) layer, and a plurality of cathode layers; wherein
the pixel definition layer is provided with a plurality of pixel openings and is connected to the substrate;
the plurality of pixel structures are disposed in different pixel openings and are connected to the substrate;
the transparent CPM layer is disposed on a side, away from the substrate, of the pixel definition layer and is provided with a plurality of cathode openings, and the transparent CPM layer is provided with a plurality of cathode openings, wherein in a thickness direction of the substrate, an orthographic projection of each of the cathode openings covers an orthographic projection of one of the pixel openings; and
each of the cathode layers is disposed on a side, away from the pixel definition layer, of one of the pixel structures and is connected to the pixel structure, and a position of each of the cathode layers corresponds to a position of one of the cathode openings.

In some embodiments, in the thickness direction of the substrate, an orthographic projection of the transparent CPM layer is not overlapped with an orthographic projection of each of the cathode layers.

In some embodiments, a thickness of a cathode layer on the transparent CPM layer is less than a thickness of a cathode layer in the pixel opening.

In some embodiments, an angle between an inner side wall of each of the pixel openings and a side surface, close to the substrate, of the pixel definition layer is less than a preset angle threshold.

In some embodiments, the preset angle threshold is 60 degrees.

In some embodiments, a thickness of the pixel definition layer is greater than a preset thickness threshold.

In some embodiments, the preset thickness threshold is 2 microns.

In some embodiments, a plurality of annular partition grooves are provided in a side surface, away from the substrate of the pixel definition layer, each of the annular partition grooves surrounding an outer side of one of the pixel openings.

In some embodiments, a groove depth of each of the annular partition grooves is greater than ⅓ of a thickness of the pixel definition layer.

In some embodiments, the transparent CPM layer is adhered to the pixel definition layer.

In some embodiments, the transparent CPM layer is an ultraviolet (UV) resistant transparent CPM layer.

In some embodiments, each of the pixel structures comprises an anode layer and an an electro-luminescence layer (EL) layer; wherein the anode layer is disposed in the pixel opening and is connected to the substrate;
the EL layer is disposed in the pixel opening, is disposed on a side, away from the substrate, of the anode layer, and is connected to the anode layer; and
the cathode layer is disposed on a side, away from the anode layer, of the EL layer and is connected to the EL layer.

In a second aspect, the embodiments of the present disclosure provide a method for preparing a display panel. The method is applied to the display panel as described in the above aspect, and includes:
connecting the pixel definition layer to the substrate, and evaporating a pixel structure into a pixel opening;
alternating a plurality of vias in the mask plate with a plurality of pixel openings, and connecting the mask plate to a side, away from the substrate, of the pixel definition layer;
evaporating a transparent CPM material to form the transparent CPM layer on a side, away from the substrate, of the pixel definition layer;
separating the mask plate from the pixel definition layer; and
evaporating a cathode material to form cathode layers on a side, away from the substrate, of the pixel structure.

In a third aspect, the embodiments of the present disclosure provide a display device. The display device includes a display panel as described in the above aspect.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following description illustrate merely some embodiments of the present disclosure, and persons of ordinary skill in the art may still derive other drawings from these accompanying drawings without creative efforts.

FIG. 1 is a schematic structure diagram of a display panel according to some embodiments of the present disclosure;

FIG. 2 is a top-view schematic structure diagram of a transparent CPM layer and a cathode layer according to some embodiments of the present disclosure;

FIG. 3 is a schematic diagram of a method for preparing a display panel according to some embodiment of the present disclosure;

FIG. 4 is a schematic diagram of a method for preparing a display panel according to some embodiments of the present disclosure;

FIG. 5 is a schematic structure diagram of a display panel according to some embodiments of the present disclosure;

FIG. 6 is a top-view schematic structure diagram of a transparent CPM layer, a cathode layer, and a pixel definition layer according to some embodiments of the present disclosure;

FIG. 7 is a schematic structure diagram of a display panel according to some embodiments of the present disclosure;

FIG. 8 is a schematic structure diagram of a display panel according to some embodiments of the present disclosure; and

FIG. 9 is a flowchart of a method for preparing a display panel according to some embodiments of the present disclosure.

### DETAILED DESCRIPTION

For clearer descriptions of the objectives, technical solutions, and advantages of the present disclosure, embodiments of the present disclosure are described in detail hereinafter with reference to the accompanying drawings.

In the related art, a grid-shaped source data (SD) trace is provided on the display panel to reduce current and resistance (IR) drop, thereby reducing the transmittance of the display panel. Table 1 below shows a comparison between transmittances of display panels without a grid-shaped SD trace and transmittances of display panels with a grid-shaped SD trace.

TABLE 1

| Pixel gap | 19 μm | 18 μm | 17 μm |
|---|---|---|---|
| Transmittance of display panel without | 1.75% | 1.70% | 1.65% |
| grid-shaped SD trace | | | |
| Transmittance of Display panel with | 1.60% | 1.56% | 1.45% |
| grid-shaped SD trace | | | |

As can be seen from Table 1, among the above three display panels with different pixel gaps, all of the display panels provided with the grid-shaped SD trace have a lower transmittance, which cannot meet the high transmittance requirements of the current under-screen optical fingerprint identification technology.

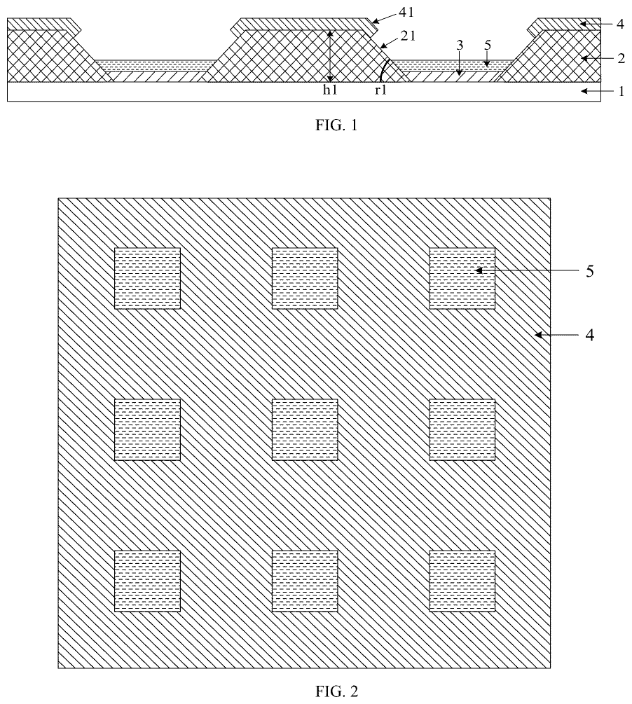

FIG. 1 is a schematic structure diagram of a display panel according to some embodiments of the present disclosure. Referring to FIG. 1, the display panel includes a substrate 1, a pixel definition layer 2, a plurality of pixel structures 3, a transparent cathode patterning material (CPM) layer 4, and a plurality of cathode layers 5.

The substrate 1 mainly serves to carry the pixel structures 3, materials of which may be plastic, glass, and the like.

The pixel definition layer 2 and the substrate 1 are connected and are stacked. The pixel definition layer 2 is configured to divide the position of the plurality of pixel structures 3 on the substrate 1, and is provided with a plurality of pixel openings 21. The plurality of pixel openings 21 are evenly distributed on the pixel definition layer 2, and may be rectangular, diamond-shaped, and the like, which are not limited in the embodiments of the present disclosure.

The plurality of pixel structures 3 are disposed in different pixel openings 21 and are connected to the substrate 1. Each of the cathode layers 5 is disposed on a side of a pixel structure 3 away from the pixel definition layer 2 and is connected to the pixel structure 3. The position of each of the pixel structures 3 corresponds to the position of one cathode opening 41, and the pixel structures 3 is connected to the cathode layer 5. By applying a voltage to both ends of the pixel structure 3 and the cathode layer 5, the pixel structure 3 is caused to emit light, which in turn causes the display panel to display an image.

The material of the cathode layer 5 may be metal or synthetic metal, for example, indium tin oxide (ITO), magnesium argentum alloy (MgAg), argentum (Ag), aluminum (Al), magnesium (Mg), and the like, which is not limited in the embodiments of the present disclosure.

The transparent CPM layer 4 is disposed on a side of the pixel definition layer 2 away from the substrate 1 and is connected to the pixel definition layer 2. In addition, the transparent CPM layer 4 is provided with a plurality of cathode openings 41. In a thickness direction of the substrate 1, an orthographic projection of each of the cathode openings 41 covers an orthographic projection of one of the pixel openings 21. In this way, the transparent CPM layer 4 can be used for the cathode patterning process to obtain the plurality of cathode layers 5, and the positions of the plurality of cathode layers 5 are directly opposite to the positions of the plurality of pixel openings 21.

The material of the transparent CPM layer 4 may be a high fluoride-containing compound, which is less compatible with the cathode material. The plurality of cathode openings 41 in the transparent CPM layer 4 may be independently spaced according to the demand, or may be arranged in rows and columns. For example, the plurality of cathode openings 41 may be arranged according to a grid shape, and the like, which is not limited in the embodiments of the present disclosure.

In preparation for the display panel, the pixel definition layer 2 is connected to a side of the substrate 1, and the plurality of pixel structures 3 are arranged in the plurality of pixel openings 21 of the pixel definition layer 2 and connected to the substrate 1. Then, the transparent CPM layer 4 is evaporated on a side of the pixel definition layer 2 away from the substrate 1, such that the plurality of cathode openings 41 are formed in the transparent CPM layer 4. The orthographic projections of the plurality of cathode openings 41 on the substrate 1 cover the orthographic projections of the pixel openings 21 on the substrate 1. In this way, the transparent CPM is provided in regions of the pixel definition layer 2 other than the regions corresponding to the cathode openings 41.

After the transparent CPM layer 4 is formed, a cathode material is evaporated on a side of the transparent CPM layer 4 away from the pixel definition layer 2. Due to the poor compatibility between the cathode material and the transparent CPM material, it is difficult for the cathode material to be adhered to the transparent CPM material, and thus the cathode material may be adhered, through the plurality of cathode openings 41 in the transparent CPM layer 4, to the pixel structures 3 corresponding to the position of the cathode openings 41, such that each of the pixel structures 3 is connected to one corresponding cathode layer 5.

In this way, a display panel as illustrated in FIG. 2 is formed. FIG. 2 is a top-view schematic structure diagram of a transparent CPM layer 4 and a plurality of cathode layers 5. Combined with FIGS. 1 and 2, it can be seen that in the display panel, the cathode layers 5 are provided only at a position directly opposite to the pixel structures 3, and the transparent CPM layer 4 is provided at the other positions. As the transmittance of the transparent CPM layer 4 is much higher than the transmittance of the cathode layer 5, the transmittance of the display panel using this structure can be effectively improved.

Moreover, as the cathode material is difficult to be adhered to the transparent CPM material, the transparent CPM layer 4 may not be adhered to the cathode material, or only a small amount of the cathode material may be adhered to the cathode material. In either case, as the transparent CPM layer 4 has a very high transmittance, and little or even no cathode material is on the transparent CPM layer 4, the transmittance of the display panel using this structure can be effectively improved.

Referring to Table 2, Table 2 shows the experimentally measured transmittance of the display panel in the embodiments of the present disclosure for three different pixel gaps.

TABLE 2

| Pixel gap | 19 μm | 18 μm | 17 μm |
|---|---|---|---|
| Transmittance of display | 1.75% | 1.70% | 1.65% |
| panel without grid-shaped | | | |
| SD trace | | | |
| Transmittance of display | 1.60% | 1.56% | 1.45% |
| panel with grid-shaped | | | |
| SD trace | | | |
| Transmittance of display | 1.92%-2.0% | 1.90%-1.93% | 1.77%-1.80% |
| panel in embodiments of | | | |
| the present disclosure | | | |

Referring to Table 2, it can be seen that the transmittance of the display panel in the embodiments of the present disclosure is significantly higher than that of the related art.

In some embodiments, the structure corresponding to the case where the cathode material is not adhered to the transparent CPM layer 4 is described: in the thickness direction of the substrate 1, an orthographic projection of the transparent CPM layer 4 is not overlapped with an orthographic projection of the cathode layer 5.

In this way, reasonable space can be respectively allocated for the transparent CPM layer 4 and the plurality of cathode layers 5, a problem of the transparent CPM layer 4 occupying too much region and thus causing the cathode layer 5 to occupy too little region is avoided, and a problem of the transparent CPM layer 4 occupying too little region and thus causing the cathode layer 5 to occupy too much region is also avoided.

In the case that the cathode layer 5 occupies too little region, the display effect of the display panel may be reduced. In the case that the cathode layer 5 occupies too much region and the transparent CPM layer 4 occupies too little region, the transmittance of the display panel may be decreased. Therefore, the structure that the transparent CPM layer 4 does not overlap with the cathode layer 5 in the embodiments of the present disclosure may increase the transmittance of the display panel and improve the display effect of the display panel.

In some embodiments, the pixel opening 21 may be positive prism-shaped, i.e.: an angle (e.g. the angle r1 in FIG. 1) between an inner side wall of each of the pixel openings 21 and a side surface of the pixel definition layer 2 close to the substrate 1 may be less than 90 degrees, and correspondingly, an angle between the inner side walls of the pixel opening 21 and the side surface of the pixel definition layer 2 away from the substrate 1 is greater than 90 degrees. In this way, each inner side wall of the pixel opening 21 is formed into a sloped surface, which facilitates the layer structure to climb during the evaporation of the pixel structure 3 and the cathode layer 5, thereby reducing the risk of the layer structure fracture.

In some embodiments, to avoid the problem that the transparent CPM layer 4 occupies too much region and thus the cathode layer 5 occupies too little region, and to realize a structure in which the transparent CPM layer 4 is not overlapped with the cathode layer 5, the pixel definition layer 2 may be set as follows: the angle (the angle r1 in FIG. 1) between the inner side wall of the pixel opening 21 and the side surface of the pixel definition layer 2 close to the substrate 1 is less than a preset angle threshold, which may be less than 90 degrees.

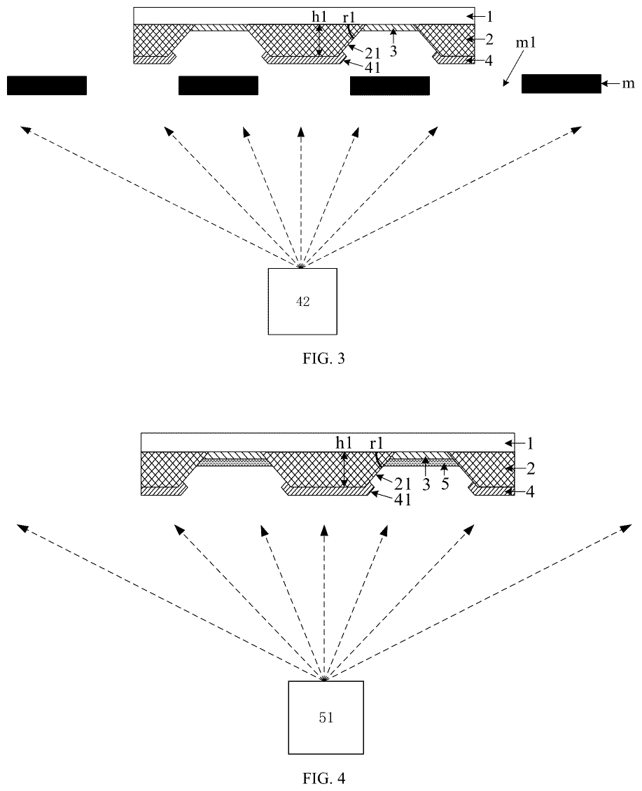

Referring to FIG. 3, in the process of preparing the display panel, before evaporating the transparent CPM material 42, a mask plate m needs first to be installed on the side of the pixel definition layer 2 away from the substrate 1, and the mask plate m is connected to the pixel definition layer 2 by using a magnet. The mask plate m has a plurality of vias m1, and the plurality of vias m1 need to be alternated with the plurality of pixel openings 21, i.e., in the thickness direction of the substrate 1, an orthographic projection of a via m1 is not overlapped the orthographic projection of the pixel opening 21. After the mask plate m is installed, the transparent CPM material 42 can be evaporated to pass through the vias m1, such that the transparent CPM layer 4 with the cathode openings 41 is formed at the position of the pixel definition layer 2 corresponding to the vias m1.

Referring to FIG. 4, the cathode material 51 is evaporated, such that the cathode material 51 is not adhered to the transparent CPM layer 4, therefore the evaporation-molded cathode material is separated into a plurality of discrete cathode layers 5 by the transparent CPM layer 4 and each of the discrete cathode layers 5 is connected to one pixel structure 3, respectively.

In the above preparation process, due to the presence of a magnet and other structures between the mask plate m and the pixel definition layer 2, there is inevitably a gap between the mask plate m and the pixel definition layer 2. Due to the presence of the gap, a circle of shadow is formed in the evaporation of the transparent CPM material, i.e., a circle of transparent CPM larger than the outside of the via m1, and the circle of shadow makes the region occupied by the transparent CPM layer 4 increase.

To avoid the above-described problem that the transparent CPM layer 4 is enlarged due to the shadow and thus the region of the cathode layer 5 is occupied, the angle r1 may be set smaller than a preset angle threshold, and a length and an area of the inner side wall of the pixel opening 21 may be increased, such that the shadow is formed on the inner side wall of the pixel opening 21 at a position away from the pixel structure 3, and the formed transparent CPM layer 4 does not occupy a position used for the cathode layer 5. In this way, it is ensured that a reasonable region of the cathode layer 5 is set to be in full contact with the pixel structure 3, thereby improving the display effect of the display panel.

In the embodiments of the present disclosure, the preset angle threshold maybe 60 degrees, or may be set according to the actual situation of the display panel. In the case that the area occupied by the transparent CPM layer 4 is too large, the angle r1 may be appropriately reduced, such that the length and the area of the inner side wall of the pixel opening 21 are increased, and thus the range of the area occupied by the transparent CPM layer 4 is reduced.

In some embodiments, in the case that the adjustment of the angle r1 does not satisfy the setting of the region occupied by the transparent CPM layer 4, and the angle r1 has been set as described above, the following setting is made: the thickness of the pixel definition layer 2 (e.g., h1 in FIG. 1) is greater than a preset thickness threshold.

In the case that the thickness of the pixel definition layer 2 is greater than the preset thickness threshold, the length and the area of the inner side wall of the pixel opening 21 are also larger. Therefore, the pixel definition layer 2 can be set according to the angle r1 and the thickness of h1, so as to ensure that the length and the area of the inner side wall of the pixel opening 21 are large enough to make the region occupied by the formed transparent CPM layer 4 more reasonable.

In the embodiments of the present disclosure, the preset thickness threshold may be 2 microns or may be set according to the actual situation of the display panel. In the case that the region occupied by the transparent CPM layer 4 is too large, the thickness of h1 may be appropriately increased, such that the length and the area of the inner side wall of the pixel opening 21 are increased, and thus the range of the region occupied by the transparent CPM layer 4 is reduced.

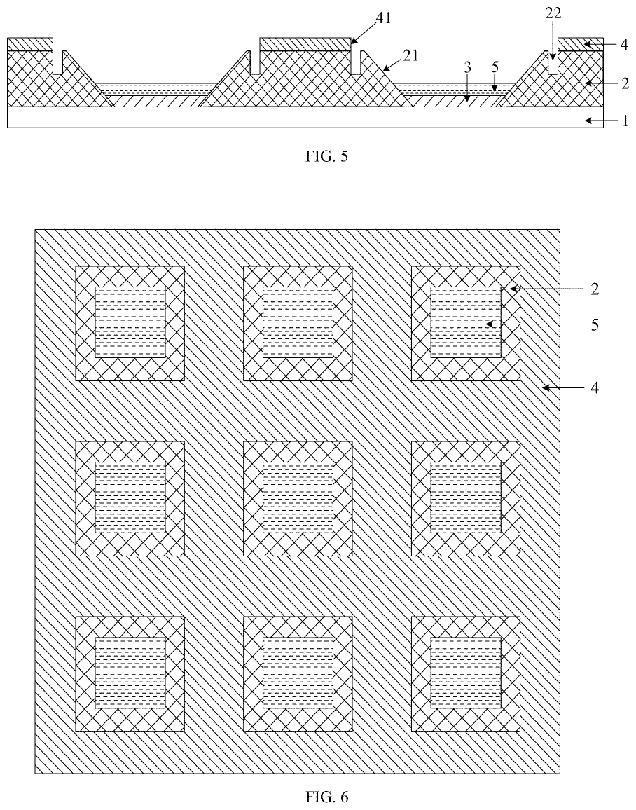

In some embodiments, to avoid the problem that the transparent CPM layer 4 occupies too little region and thus the cathode layer 5 occupies too much region, and also to avoid the problem that the transparent CPM layer 4 occupies too much region and thus the cathode layer 5 occupies too little region (the transparent CPM layer 4 occupies too little region either because the via m1 of the mask plate m is set to be too large or because the via m1 becomes too large due to the deformation of the mask plate m caused by the alternating hot and cold in the process of evaporation), to realize a structure in which the transparent CPM layer 4 is not overlapped with the cathode layer 5, the pixel definition layer 2 may be set as follows: referring to FIG. 5, a plurality of annular partition grooves 22 are provided in a side surface of the pixel definition layer 2 away from the substrate 1, the annular partition grooves 22 surrounding an outer side of the pixel opening 21.

One annular partition groove 22 is provided on the outer side of each of the pixel openings 21, such that excessive transparent CPM material or excessive cathode material may fall into the annular partition groove 22 during evaporation. Referring to FIG. 6 (FIG. 6 is a top view schematic structure diagram of the transparent CPM layer 4, the cathode layer 5, and the pixel definition layer 2), it can be seen that the annular partition groove 22 blocks the transparent CPM layer 4 from occupying the cathode layer 5 and also blocks the cathode layer 5 from occupying the transparent CPM layer 4, such that reasonable setting areas for both the transparent CPM layer 4 and the cathode layer 5 are ensured, thereby improving the transmittance of the display panel and improving the display effect of the display panel.

In the embodiments of the present disclosure, the annular space recess 22 may be any reasonable shape, e.g. cross-section perpendicular to the substrate 1 of the annular partition recess 22 may be rectangular, or maybe other reasonable shapes, which are not limited in the embodiments of the present disclosure.

The groove depth of the annular partition groove 22 may be greater than ⅓ of the thickness of the pixel definition layer 2, which makes the blocking effect better.

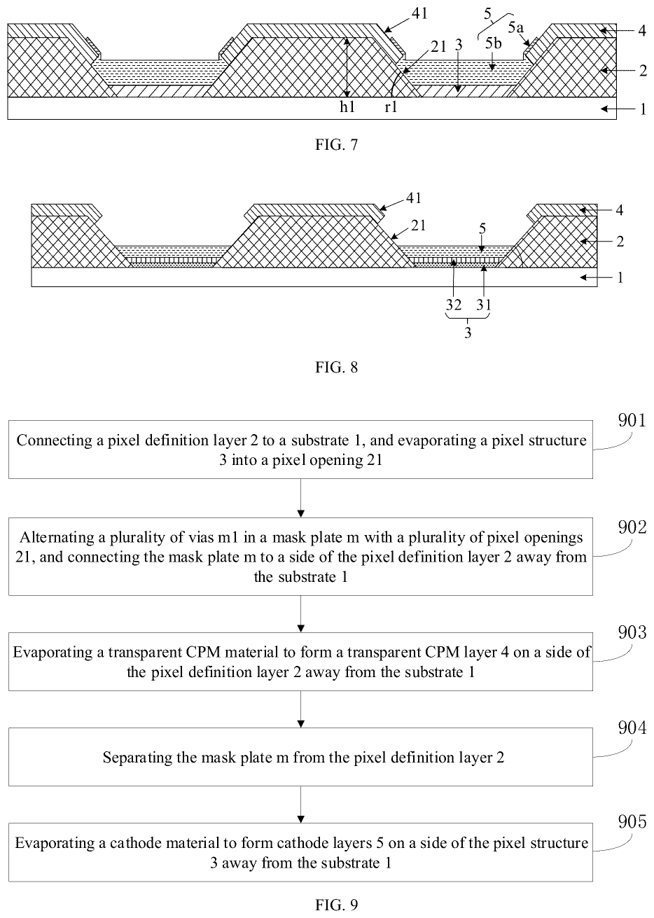

In some embodiments, the structure corresponding to the case where only a small amount of cathode material is adhered to the transparent CPM layer 4 is described: referring to FIG. 7, the thickness of the cathode layer 5 (i.e. 5a in FIG. 7) on the transparent CPM layer 4 is less than the thickness of the cathode layer 5 (i.e. 5b in FIG. 7) in the pixel opening 21.

In this way, even though a small amount of cathode material is adhered to the transparent CPM layer 4, part 5a of the cathode layer 5 has little effect on the transmittance at the transparent CPM layer 4 because the transmittance of the transparent CPM layer 4 is very high, and thus the transmittance of the display panel can still be effectively improved.

In some embodiments, the pixel opening 21 may be positive prism-shaped, i.e.: an angle (e.g. the angle r1 in FIG. 7) between the inner side wall of each of the pixel openings 21 and the side surface of the pixel definition layer 2 close to the substrate 1 may be less than 90 degrees, and correspondingly, an angle between the inner side wall of the pixel opening 21 and the side surface of the pixel definition layer 2 away from the substrate 1 is greater than 90 degrees. In this way, each inner side wall of the pixel opening 21 is formed into a sloped surface, which facilitates a layer structure to climb during the evaporation of the pixel structure 3 and the cathode layer 5, thereby reducing the risk of the layer structure fracture.

In some embodiments, to avoid the problem that the transparent CPM layer 4 occupies too much region and thus the cathode layer 5 occupies too little region, the pixel definition layer 2 may be set as follows: the angle (e.g., the angle r1 in FIG. 7) between the inner side wall of the pixel opening 21 and the side surface of the pixel definition layer 2 close to the substrate 1 is less than a preset angle threshold, which may be less than 90 degrees.

To avoid the problem that the transparent CPM layer 4 is enlarged due to the shadow and thus the region of the cathode layer 5 is occupied, the angle r1 is set to be less than the preset angle threshold, and a length and an area of the inner side wall of the pixel opening 21 may be increased, such that the shadow is formed on the inner side wall of the pixel opening 21 at a position away from the pixel structure 3, and the formed transparent CPM layer 4 does not occupy a position used for the cathode layer 5. In this way, it is ensured that a reasonable region of the cathode layer 5 is set to be in full contact with the pixel structure 3, thereby improving the display effect of the display panel.

In the embodiments of the present disclosure, the preset angle threshold maybe 60 degrees, or may be set according to the actual situation of the display panel. In the case that the area occupied by the transparent CPM layer 4 is too large, the angle r1 may be appropriately reduced, such that the length and the area of the inner side wall of the pixel openings 21 are increased, and thus the range of the area occupied by the transparent CPM layer 4 is reduced.

In some embodiments, in the case that the angle r1 has been set as described above, the following setting is made: the thickness of the pixel definition layer 2 (e.g. h1 in FIG. 7) is greater than a preset thickness threshold.

In the case that the thickness of the pixel definition layer 2 is greater than a preset thickness threshold, the length and area of the inner side wall of the pixel opening 21 are also larger. Therefore, the pixel definition layer 2 can be set according to the angle r1 and the thickness of h1, so as to ensure that the length and area of the inner side wall of the pixel opening 21 are large enough to make the region occupied by the formed transparent CPM layer 4 more reasonable.

In the embodiments of the present disclosure, the preset thickness threshold may be 2 microns or may be set according to the actual situation of the display panel. In the case that the region occupied by the transparent CPM layer 4 is too large, the thickness of h1 may be appropriately increased, such that the length and the area of the inner side wall of the pixel openings 21 are increased, and thus the range of the region occupied by the transparent CPM layer 4 is reduced.

In some embodiments, to avoid the problem that the transparent CPM layer 4 occupies too little region and thus the cathode layer 5 occupies too much region, and also to avoid the problem that the transparent CPM layer 4 occupies too much region and thus the cathode layer 5 occupies too little region (the transparent CPM layer 4 occupies too little region either because the via m1 of the mask plate m is set too large or because the via m1 becomes too large due to the deformation of the mask plate m caused by the alternating hot and cold in the process of evaporation), the pixel definition layer 2 may be set as follows: referring to FIG. 5, a plurality of annular partition grooves 22 are provided on the side surface of the pixel definition layer 2 away from the substrate 1, the annular partition grooves 22 surrounding an outer side of the pixel opening 21.

One annular partition groove 22 is provided on the outer side of each of the pixel openings 21, such that excessive transparent CPM material or excessive cathode material may fall into the annular partition groove 22 during evaporation, and thus the annular partition groove 22 blocks the transparent CPM layer 4 from occupying the cathode layer 5 and also blocks the cathode layer 5 from occupying the transparent CPM layer 4. In this way, reasonable setting areas for both the transparent CPM layer 4 and the cathode layer 5 are ensured, thereby improving the transmittance of the display panel and improving the display effect of the display panel.

In the embodiments of the present disclosure, the annular partition recess 22 may be any reasonable shape, e.g. cross-section perpendicular to the substrate 1 of the annular partition recess 22 may be rectangular, or maybe other reasonable shapes, which is not limited in the embodiments of the present disclosure.

The groove depth of the annular partition recess 22 may be greater than ⅓ of the thickness of the pixel definition layer 2, which makes the blocking effect better.

In some embodiments, the transparent CPM layer 4 is prepared by using the above-described evaporation method. The structure of the prepared transparent CPM layer 4 satisfies that the transparent CPM layer 4 is adhered to the pixel definition layer 2, i.e., during the process of evaporation of the CPM material, the CPM material is shaped on the side surface of the pixel definition layer 2 away from the substrate 1.

In some embodiments, the transparent CPM layer 4 may be an ultraviolet (UV) resistant transparent CPM layer, so as to improve the UV-resistant performance of the display panel due to the current requirement of UV light trustworthiness of the display panel.

In some embodiments, the display panel in the embodiments of the present disclosure may be a display panel in any of display device. Exemplarily, referring to FIG. 8, the display panel may be a display panel in an OLED display device, and the structure of pixel structure 3 may be: the pixel structure 3 includes an anode layer 31 and an electro-luminescence layer (EL) layer 32; the anode layer 31 is disposed in the pixel opening 21 and is connected to the substrate 1; the EL layer 32 is disposed in the pixel opening 21, is disposed on a side of the anode layer 31 away from the substrate 1, and is connected to the anode layer 31; and the cathode layer 5 is disposed on a side of the EL layer 32 away from the anode layer 31 and is connected to the EL layer 32.

In the case that a voltage is applied to the anode layer 31 and the cathode layer 5, the anode layer 31 and the cathode layer 5 inject holes and electrons into the EL layer respectively. The holes and the electrons meet in the EL layer 32 and generate energy, and the energy is ultimately released in the form of light emission to achieve light emission from the pixel structure.

The EL layer 32 may include an electron transmission layer, a hole-blocking layer, a light-emitting layer, and a hole transmission layer, which are sequentially stacked. The electron transmission layer is disposed on a side of the cathode layer 5 close to the substrate 1 and is connected to the cathode layer 5, and the hole transmission layer is disposed on a side of the anode layer 31 away from the substrate 1 and is connected to the anode layer 31.

In addition, the above structure is only an example, and the pixel structure 3 may be any reasonable structure, which is not limited in the embodiments of the present disclosure.

The embodiments of the present disclosure provide a method for preparing a display panel. The method is applied to any one of the display panels as described in the above embodiments. Referring to FIG. 9, the method includes the following processes:

In 901, a pixel definition layer 2 is connected to the substrate 1, and a pixel structure 3 is evaporated into a pixel opening 21.

In 902, a plurality of vias m1 in a mask plate m are alternated with a plurality of pixel openings 21, and the mask plate m is connected to a side of the pixel definition layer 2 away from a substrate 1.

By using a magnet, the mask plate m is connected to the side of the pixel definition layer 2 away from the substrate 1, such that the plurality of vias m1 in the mask plate m are alternated with the plurality of pixel openings 21 in the pixel definition layer 2, i.e., in a thickness direction of the substrate 1, an orthographic projection of a via m1 is not overlapped with an orthographic projection of a pixel opening 21.

In 903, a transparent CPM material is evaporated to form a transparent CPM layer 4 on a side of the pixel definition layer 2 away from the substrate 1.

The transparent CPM material is evaporated, such that the transparent CPM material passes through the plurality of vias m1 in the mask plate m and then reaches the pixel definition layer 2 to form the transparent CPM layer 4 on the pixel definition layer 2. The mask plate m causes the formed transparent CPM layer 4 to be provided with a plurality of cathode openings 41. In the thickness direction of the substrate 1, an orthographic projection of a cathode opening 41 covers the orthographic projection of the pixel opening 21.

In 904, the mask plate m is separated from the pixel definition layer 2.

After the transparent CPM layer 4 is formed, the mask plate m is removed from the pixel definition layer 2.

In 905, a cathode material is evaporated to form cathode layers 5 on a side of the pixel structure 3 away from the substrate 1.

After the mask plate m is removed, the cathode material is evaporated. As the cathode material is very poorly compatible with the transparent CPM layer 4, the cathode material is not adhered or a small amount of the cathode material is adhered to the transparent CPM layer 4. Most of the cathode material is adhered to the pixel structure 3 which is directly opposite to the position of the cathode opening 41 through the cathode opening 41 on the transparent CPM layer 4, such that a corresponding cathode layer 5 is formed through each of the cathode openings 41, thereby completing the preparation of the display panel.

The embodiments of the present disclosure provide a display device. The display device may include any one of the display panels as described in the above embodiments. In the display panel, the transparent CPM layer 4 is alternated with a plurality of cathode layers 5 to improve the transmittance of the display panel and improve the display effect of the display device.

In some embodiments, the display device further includes a class collimator. The class collimator is disposed on a side of the substrate 1 away from the pixel definition layer 2. In the case that a user's finger is placed on the display screen of the display device, the pixel structure 3 emits light, and an optical fiber is refracted by a finger. The emissivity of ridges and valleys of the finger are different, and the light returns to the class collimator provided under the substrate 1 to image the fingerprint of the finger, such that the fingerprint of the user is identified.

In some embodiments, the display device may be an OLED display device, a liquid crystal display device, an electronic paper, a mobile phone, a tablet computer, a television, a display, a laptop computer, a digital photo frame, or a navigator, or any other product or component with a display function, which is not limited in the embodiments of the present disclosure.

Described above are merely optional embodiments of the present disclosure, and are not intended to limit the present disclosure. With the spirit and principles of this present disclosure, any modifications, equivalent substitutions, improvements, and the like should fall within the scope of protection of the present disclosure.

1. A display panel, comprising a substrate, a pixel definition layer, a plurality of pixel structures, a transparent cathode patterning material (CPM) layer, and a plurality of cathode layers; wherein
the pixel definition layer is provided with a plurality of pixel openings and is connected to the substrate;
the plurality of pixel structures are disposed in different pixel openings and are connected to the substrate;
the transparent CPM layer is disposed on a side, away from the substrate, of the pixel definition layer and is connected to the pixel definition layer, and the transparent CPM layer is provided with a plurality of cathode openings, wherein in a thickness direction of the substrate, an orthographic projection of each of the cathode openings covers an orthographic projection of one of the pixel openings; and
each of the cathode layers is disposed on a side, away from the pixel definition layer, of one of the pixel structures and is connected to the pixel structure, and a position of each of the cathode layers corresponds to a position of one of the cathode openings.

2. The display panel according to claim 1, wherein in the thickness direction of the substrate, an orthographic projection of the transparent CPM layer is not overlapped with an orthographic projection of each of the cathode layers.

3. The display panel according to claim 1, wherein a thickness of a cathode layer on the transparent CPM layer is less than a thickness of a cathode layer in the pixel opening.

4. The display panel according to claim 2, wherein an angle between an inner side wall of each of the pixel openings and a side surface, close to the substrate, of the pixel definition layer is less than a preset angle threshold.

5. The display panel according to claim 4, wherein the preset angle threshold is 60 degrees.

6. The display panel according to claim 4, wherein a thickness of the pixel definition layer is greater than a preset thickness threshold.

7. The display panel according to claim 6, wherein the preset thickness threshold is 2 microns.

8. The display panel according to claim 2, wherein a plurality of annular partition grooves are provided in a side surface, away from the substrate, of the pixel definition layer, each of the annular partition grooves surrounding an outer side of one of the pixel openings.

9. The display panel according to claim 8, wherein a groove depth of each of the annular partition grooves is greater than ⅓ of a thickness of the pixel definition layer.

10. The display panel according to claim 1, wherein the transparent CPM layer is adhered to the pixel definition layer.

11. The display panel according to claim 1, wherein the transparent CPM layer is an ultraviolet (UV) resistant transparent CPM layer.

12. The display panel according to claim 1, wherein each of the pixel structures comprises an anode layer and an electro-luminescence layer (EL) layer; wherein
the anode layer is disposed in the pixel opening and is connected to the substrate;
the EL layer is disposed in the pixel opening, is disposed on a side, away from the substrate, of the anode layer, and is connected to the anode layer; and
the cathode layer is disposed on a side, away from the anode layer, of the EL layer and is connected to the EL layer.

13. A method for preparing a display panel, applied to the display panel as defined in claim 1, comprising:
connecting a pixel definition layer to a substrate, and evaporating a pixel structure into a pixel opening;
alternating a plurality of vias in a mask plate with a plurality of pixel openings, and connecting the mask plate to a side, away from the substrate, of the pixel definition layer;
evaporating a transparent CPM material to form a transparent CPM layer on a side, away from the substrate, of the pixel definition layer;
separating the mask plate from the pixel definition layer; and
evaporating a cathode material to form cathode layers on a side, away from the substrate, of the pixel structure.

14. A display device, comprising a display panel, wherein the display panel comprises a substrate, a pixel definition layer, a plurality of pixel structures, a transparent cathode patterning material (CPM) layer, and a plurality of cathode layers; wherein
the pixel definition layer is provided with a plurality of pixel openings and is connected to the substrate;
the plurality of pixel structures are disposed in different pixel openings and are connected to the substrate;
the transparent CPM layer is disposed on a side, away from the substrate, of the pixel definition layer and is connected to the pixel definition layer, and the transparent CPM layer is provided with a plurality of cathode openings, wherein in a thickness direction of the substrate, an orthographic projection of each of the cathode openings covers an orthographic projection of one of the pixel openings; and
each of the cathode layers is disposed on a side, away from the pixel definition layer, of one of the pixel structures and is connected to the pixel structure, and a position of each of the cathode layers corresponds to a position of one of the cathode openings.

15. The display device according to claim 14, wherein in the thickness direction of the substrate, an orthographic projection of the transparent CPM layer is not overlapped with an orthographic projection of each of the cathode layers.

16. The display device according to claim 14, wherein a thickness of a cathode layer on the transparent CPM layer is less than a thickness of a cathode layer in the pixel opening.

17. The display device according to claim 15, wherein an angle between an inner side wall of each of the pixel openings and a side surface, close to the substrate, of the pixel definition layer is less than a preset angle threshold.

18. The display device according to claim 17, wherein the preset angle threshold is 60 degrees.

19. The display device according to claim 17, wherein a thickness of the pixel definition layer is greater than a preset thickness threshold.

20. The display device according to claim 19, wherein the preset thickness threshold is 2 microns.
